(19) United States
(12) Patent Application Publication
(10) Pub. No.: US 2020/0118991 A1
(43) Pub. Date: Apr. 16, 2020

(54) PRE-PATTERNED FINE-PITCH BOND PAD INTERPOSER

(71) Applicant: Intel Corporation, Santa Clara, CA (US)

(72) Inventors: James ZHANG, Folsom, CA (US); Yi XU, Folsom, CA (US)

(21) Appl. No.: 16/160,197

(22) Filed: Oct. 15, 2018

(51) Int. Cl. H01L 25/18; H01L 23/00; H01L 23/31; H01L 23/433

(52) U.S. Cl. CPC H01L 25/18; H01L 24/49; H01L 24/09; H01L 2924/381; H01L 23/3121; H01L 23/4334; H01L 24/97; H01L 24/85

(57) ABSTRACT

Embodiments disclosed herein include electronic packages and methods of forming such electronic packages. In an embodiment, the electronic package comprises, a package substrate, a die stack on the package substrate, and a mold layer encapsulating the die stack. In an embodiment, the electronic package further comprises a bond pad having a first surface and a second surface, where the die stack is electrically coupled to the first surface of the bond pad with a wire bond, and the second surface of the bond pad is substantially coplanar with a surface of the mold layer.

### TECHNICAL FIELD

Embodiments of the present disclosure relate to electronic packaging, and more particularly, to electronic packages with pre-patterned fine-pitch bond pads for wire bonding.

### BACKGROUND

As memory demands continue to increase, the drive for higher density memory components continues to accelerate. In order to increase the density of memory in a given form factor, multiple dies are being packaged in a stacked configuration. Stacking dies is not without issue. Particularly, the stacked dies need to be electrically coupled to the package substrate. Several solutions exist for electrically coupling the stacked dies to the package substrate.

In one configuration, vertical wires from each of the dies are coupled to a redistribution layer (RDL) formed over the stacked dies. Such a configuration requires a high temperature process. Furthermore, the special vertical wire process increases processing costs. Additionally, the vertical wires have an inherent variability in their positioning, which makes it difficult to make the connections in a high volume manufacturing environment.

An additional configuration for making interconnects to stacked dies is by using through mold vias. Through mold vias stack dies are connected with solder in laser drilled vias. Such solutions suffer from pitch and size limitations that are constrained by the part thickness. Through mold vias, therefore, are not able to accommodate high I/O components. Additionally, through mold vias are difficult to implement in small form factor (Z-height), and also require larger component area (X-Y). Accordingly, such configurations are not suitable for high density and high performance electronic packages.

### BRIEF DESCRIPTION OF THE DRAWINGS

FIG. 1 is a cross-sectional illustration of an electronic package that comprises a plurality of die modules, where each die module includes pre-patterned, fine-pitch bond pads, in accordance with an embodiment.

FIG. 2A is a cross-sectional illustration of an interposer with pre-patterned, fine-pitch bond pads, in accordance with an embodiment.

FIG. 2B is a cross-sectional illustration after a die stack is positioned on the interposer and wire bonds are attached, in accordance with an embodiment.

FIG. 2C is a cross-sectional illustration after a mold layer is deposited which encapsulates the die stack, in accordance with an embodiment.

FIG. 2D is a cross-sectional illustration after a carrier is mounted to the mold layer, in accordance with an embodiment.

FIG. 2E is a cross-sectional illustration after the interposer is polished back to separate the bond pad from the heat spreader, in accordance with an embodiment.

FIG. 3A is a plan view illustration of a panel level interposer with a plurality of die stacks, in accordance with an embodiment.

FIG. 3B is a zoomed in plan view illustration of the bond pad region of the interposer, in accordance with an embodiment.

FIG. 3C, is a cross-sectional illustration of the bond pad region in FIG. 3B along line C-C′, in accordance with an embodiment.

FIG. 4 is a schematic of a computing device built in accordance with an embodiment.

### EMBODIMENTS OF THE PRESENT DISCLOSURE

Described herein are electronic packages with pre-patterned fine-pitch bond pads for wire bonding and methods of forming such electronic packages. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, currently used interconnect configurations are not suitable for high density and high performance packages. Accordingly, embodiments disclosed herein include electronic packages that include pre-patterned fine-pitch pads to which wire bonds from a die stack may be made. Such embodiments have several advantages over the solutions described above. For example, the use of pre-patterned fine-pitch pads may enable quicker time to market. As will be described in greater detail below, the bond pads also allow for enhanced signal integrity power delivery (SIPD) testing. This enables improved panel level testing in order to identify any defective dies earlier in the assembly process. Additionally, embodiments disclosed herein do not require redistribution layers (RDLs). This reduces assembly costs. Embodiments also result in the formation of a heat spreader over the die stack in order to improve thermal management. Furthermore, embodiments allow for fine-pitched bond pads that enable high I/O density and enable high performance and high density electronic packages.

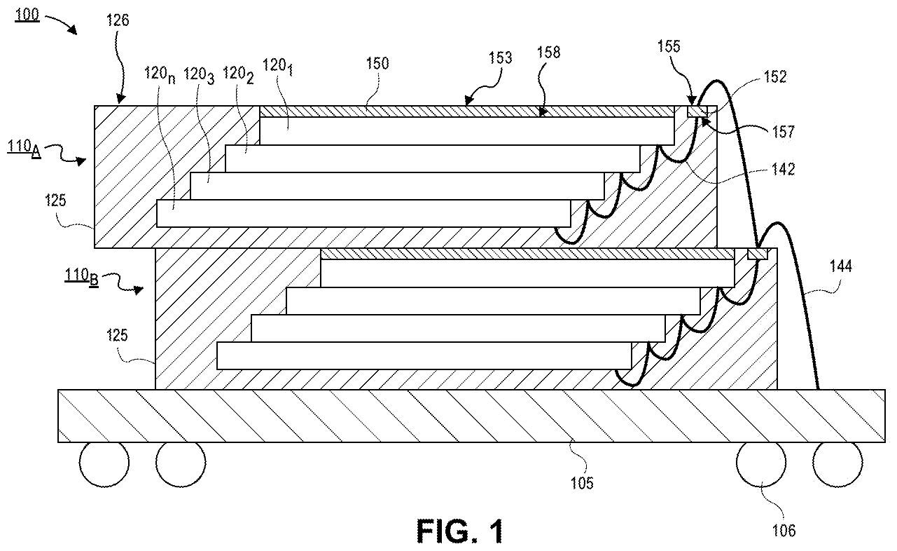

Referring now to FIG. 1, a cross-sectional illustration of an electronic package 100 is shown, in accordance with an embodiment. In an embodiment, the electronic package 100 may be formed on a package substrate 105. The package substrate 105 may be any suitable package substrate, such as those known in the art. In an embodiment, interconnects 106 (e.g., solder balls) may be formed on a surface of the package substrate 105. In an embodiment, one or more die modules 110 may be stacked on a surface of the package substrate 105 opposite from the interconnects 106. In the illustrated embodiment, a first die module 110A and a second die module 110E are shown. However, it is to be appreciated that any number of die modules 110 may be used, depending on the needs of the device. In an embodiment, the die modules 110 may be electrically coupled to the package substrate 105 with wire bonds 144.

In an embodiment, each of the die modules 110 may comprise a plurality of stacked dies 120. For example, the die module 110A includes four dies 120₁₋ₙ. However, it is to be appreciated that the die modules 110 may include any number of dies 120. In an embodiment, the dies 120₁₋ₙ, may be stacked offset from each other. The offset stacking provides access to pads on the dies (not shown) to which wire bonds 142 may be made. In an embodiment, the dies 120₁₋ₙ may be encapsulated in a mold layer 125.

In an embodiment, the stacked dies 120₁₋ₙ may be electrically coupled to pads 152. The pads 152 may be pre-patterned fine-pitched pads. For example, the pads 152 may be 50 μm×50 μm open (or any other pad dimension) with a pitch between 70 μm and 100 μm. Accordingly, the pads 152 allow for high density I/Os to enable high performance packages with a small form factor.

In an embodiment, the pads 152 may be embedded in the mold layer 125. That is, the pads 152 may have sidewalls and a first surface 157 that are covered by the mold layer 125. In an embodiment, a second surface 155 of the pads 152 may be substantially coplanar with a first surface 126 of the mold layer 125. In an embodiment, the wire bonds 142 from the dies 120 may be coupled to the first surface 157 of the pads 152. In an embodiment, the wire bonds 144 from the die modules 110 to the package substrate 105 may be coupled to the second surface 155 of the pads 152.

In an embodiment, the die modules 110 may also comprise a heat spreader 150. In an embodiment, the heat spreader 150 may have a first surface 158 that contacts one of the dies 120 in the die stack. For example, the first surface 158 of the heat spreader 150 may contact a surface of the first die 120₁ in the die stack. In an embodiment, a second surface 153 of the heat spreader 150 may be substantially coplanar with the first surface of the mold layer 126. Furthermore, the second surface 153 of the heat spreader may also be substantially coplanar with the second surface 155 of the pads 152. In an embodiment, the heat spreader 150 may comprise the same material as the pads 152.

In an embodiment, the pads 152 may be considered laterally adjacent to and spaced away from the heat spreader 150. That is, sidewalls of the pads 152 may be spaced away from sidewalls of the heat spreader 150 with a portion of the mold layer 125 between them. Accordingly, the heat spreader 150 may be electrically isolated from the pads 152.

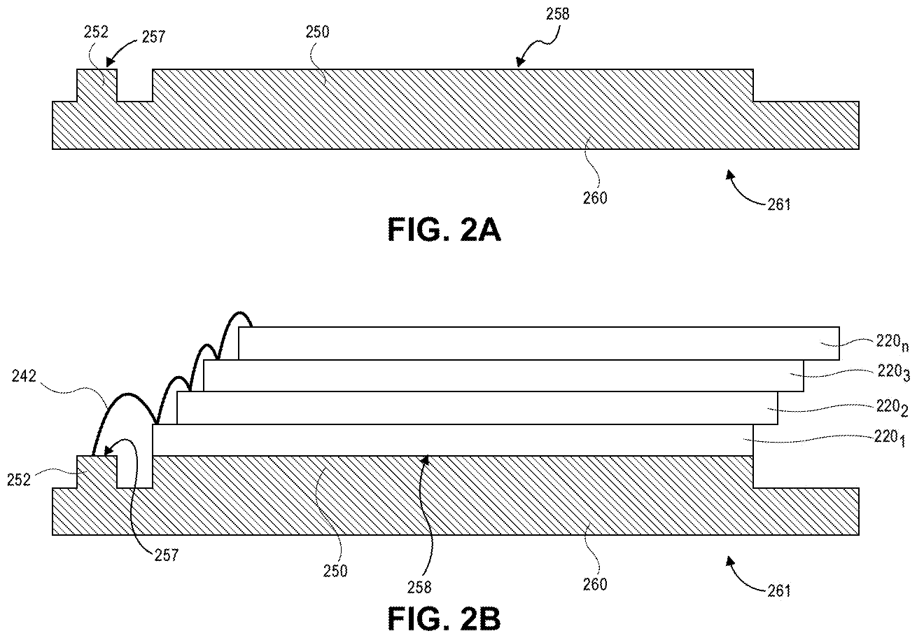

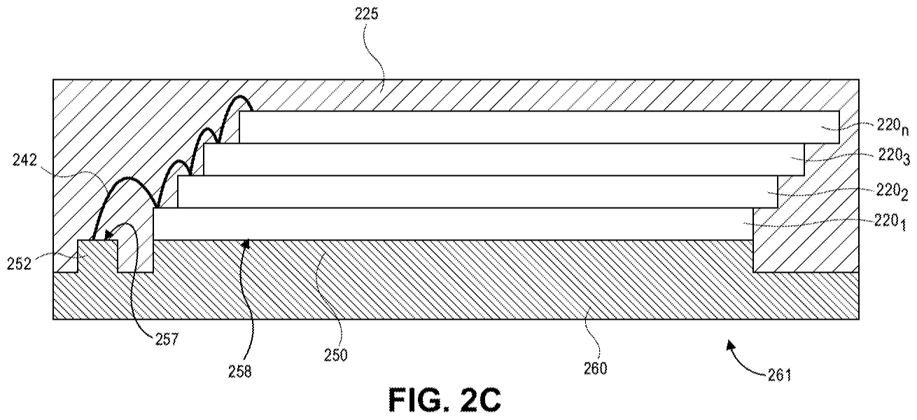

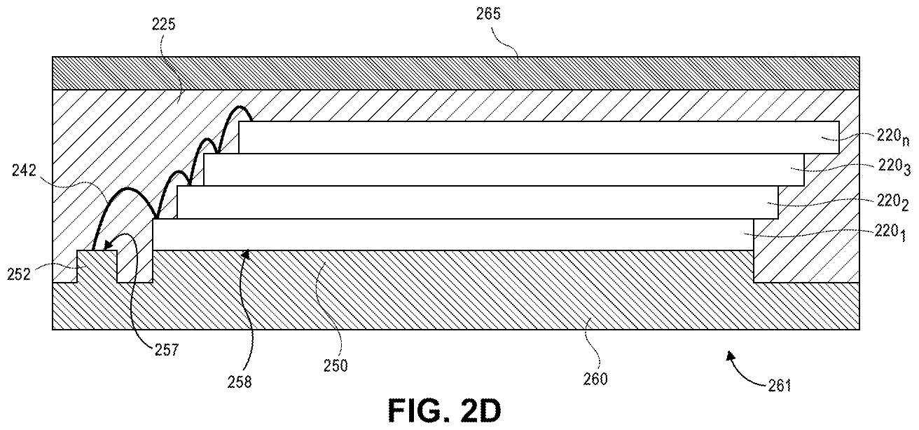

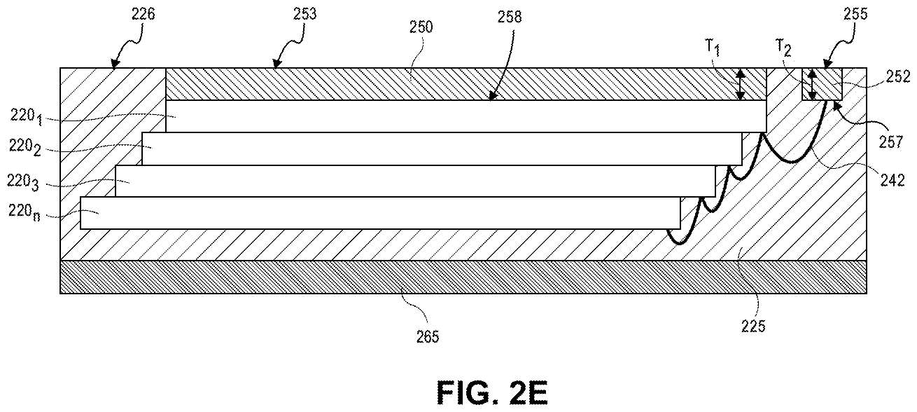

Referring now to FIGS. 2A-2E, a series of cross-sectional illustrations depict a process for forming die modules, such as the die modules 110A and 110E illustrated in FIG. 1.

Referring now to FIG. 2A, a cross-sectional illustration of an interposer 261 on which a die module is assembled is shown, in accordance with an embodiment. In an embodiment, the interposer 261 may comprise a heat spreader 250 and a pad 252 formed over an interposer substrate 260. In an embodiment, the heat spreader 250 may have a first surface 258 and the bond pad 252 may have a first surface 257 that are opposite from the interposer substrate 260. Embodiments may include first surfaces 258 and 257 that are substantially coplanar to each other. However, in other embodiments, the first surface of the bond pad 257 may not be substantially coplanar with a first surface 258 of the heat spreader 250.

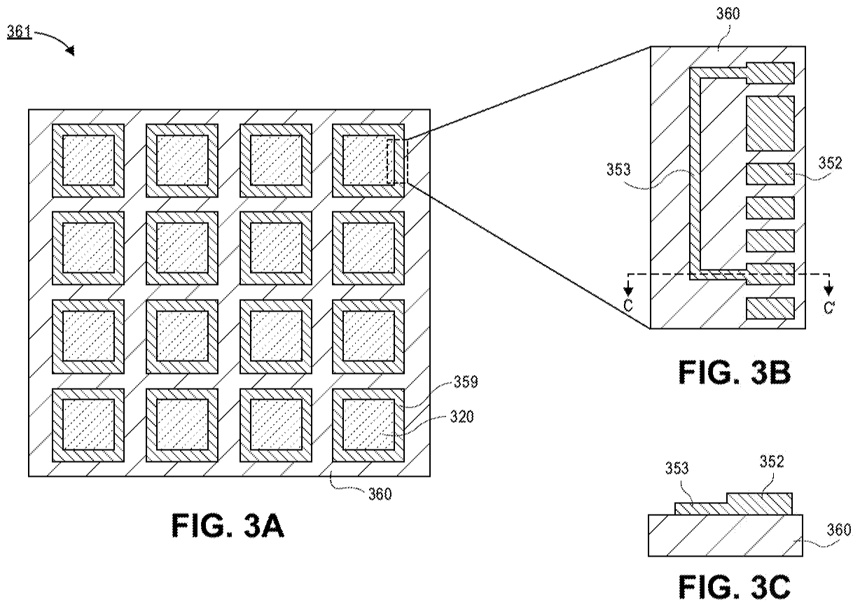

In an embodiment, the heat spreader 250 and the pad 252 may be attached to the interposer substrate 260. For example, the heat spreader 250, the pad 252, and the interposer substrate 260 may be a monolithic structure. That is, the heat spreader 250, the pad 252, and the interposer substrate 260 may be considered a single component formed from a single material. While a single pad 252 and a single heat spreader 250 are shown, it is to be appreciated that the interposer 261 may comprise a plurality of pads 252 and heat spreaders 250 in order to assemble a plurality of die modules in parallel. For example, the interposer 261 may be panel sized, quarter panel sized, or the like. A plan view illustration of such embodiments are shown below in greater detail with respect to FIG. 3A.

In an embodiment, the pads 252 may be 50 μm×50 μm open (or any other pad dimension) with a pitch between 70 μm and 100 μm. Accordingly, embodiments allow for high density I/Os with a small form factor. As used herein, the pads 252 may be referred to as “pre-patterned”. Pre-patterned refers to the pads 252 being fabricated and patterned on the interposer 261 instead of being deposited or otherwise fabricated onto the mold layer or the an RDL over the mold layer. Accordingly, the pads 252 are able to be fabricated with a small dimension and with a small pitch to enable high performance and high density electronic packages.

Referring now to FIG. 2B, a cross-sectional illustration after a die stack is mounted to the interposer 261 is shown, in accordance with an embodiment. In an embodiment, the die stack may comprise one or more dies 220₁₋ₙ that are positioned over the first surface 258 of the heat spreader 250. For example, four dies 220₁₋ₙ are shown in FIG. 2B, but it is to be appreciated that any number of dies 220 may be included in the die stack. In the illustrated embodiment, the dies 220 are shown as monolithic blocks. However, it is to be appreciated that the dies 220 may comprise any components typical of packaged dies. For example, the dies 220 may comprise die attach films (DAFs) or the like. In an embodiment, the dies 220 may be one or more of memory dies, processor dies, graphics processing dies, or the like.

In an embodiment, the dies 220 in the die stack may be stacked in an offset configuration. As such, portions of the top surface of each die are exposed. Bond pads (not shown) may be located on the exposed top surfaces and wire bonds 242 from the dies may be made, including a wire bond 242 from at least one of the dies 220 to the bond pad 252. In an embodiment, the wire bond 242 may be coupled to the first surface 257 of the bond pad 252. In an embodiment, a first die 220₁ may be in direct contact with the heat spreader 250. Accordingly, thermal management of the die module is improved since a path for heat dissipation is provided. In the illustrated embodiment, the width of the heat spreader 250 is substantially equal to the width of the bottommost die 220₁. However, it is to be appreciated that the heat spreader 250 may be wider or narrower than the bottommost die 220₁.

Referring now to FIG. 2C, a cross-sectional illustration after a mold layer 225 is deposited over the dies 220 and the interposer 261 is shown, in accordance with an embodiment. In an embodiment, the mold layer 225 may be any suitable mold material, such as epoxy or the like. The mold layer 225 may cover all exposed surfaces of the dies 220 in the die stack. That is the mold layer 225 may be formed over all of the top surfaces of the dies 220, including the topmost die 220ₙ. In an embodiment, the mold layer 225 may also fill the gap between the bond pad 252 and the heat spreader 250. In addition to providing the heat spreader 250 and the bond pads 252, the interposer 261 also aids in reducing the warpage during the molding process. Particularly, the interposer 261 provides a large stiff mass that reduces warpage and acts as a large heat sink during the molding process.

Referring now to FIG. 2D, a cross-sectional illustration after a carrier 265 is attached to the mold layer 225 is shown, in accordance with an embodiment. In an embodiment, the carrier 265 may be any suitable material that provides mechanical support to the die module during subsequent processes.

Referring now to FIG. 2E, a cross-sectional illustration after the interposer substrate 260 is removed is shown, in accordance with an embodiment. In an embodiment, the interposer substrate may be removed with a polishing process, a grinding process, or the like. After the interposer substrate 260 is removed the heat spreader 250 is electrically isolated from the pad 252. For example, the heat spreader 250 may be laterally adjacent to and separated from the pad 252. In an embodiment, a sidewall of the pad 252 may be separated from the heat spreader 250 by a portion of the mold layer 225.

In an embodiment, removing the interposer substrate 260 results in the second surface 255 of the pad 252 and the second surface 253 of the heat spreader 250 being exposed. In an embodiment, the second surfaces 255 and 253 may be substantially coplanar to each other. Embodiments may also include the second surfaces 255 and 253 being substantially coplanar with a first surface 226 of the mold layer 225. The heat spreader 250 may have a first thickness T₁ and the pad 252 may have a second thickness T₂. In some embodiments, the first thickness T₁ may be substantially equal to the second thickness T₂. In other embodiments, the first thickness T₁ may be different than the second thickness T₂. For example, the thicknesses T₁ and T₂ may be different when the first surface 257 of the pad 252 is not substantially coplanar with the first surface 258 of the heat spreader 250.

After the interposer substrate 260 is removed, the mold layer 226 may be diced to singulate individual die modules. The die modules may then be assembled into electronic packages, similar to the electronic package 100 shown in FIG. 1. In some embodiments, the die modules may be tested (using the second surface 255 of the pads 252) prior to dicing or after dicing. Accordingly, only known good die modules may be assembled into electronic packages.

Referring now to FIG. 3A, a plan view illustration of a panel level interposer 361 is shown, in accordance with an embodiment. In an embodiment, the interposer 361 may be suitable for assembling a plurality of die modules in parallel. As shown, a plurality of die stacks 320 may be attached to the interposer 361. In an embodiment, the die stacks 320 may be placed over heat spreader portions (not visible in FIG. 3A) of the interposer 361. For example, the heat spreaders may extend up from the interposer substrate 360. In an embodiment, a plurality of pad regions 359 may surround the die stacks 320 and the heat spreaders.

Referring now to FIG. 3B, a zoomed in view of the pad regions 359 are shown, in accordance with an embodiment. As shown, a plurality of discrete pads 352 may be formed over the interposer substrate 360. In an embodiment, the pads 352 may be 50 μm×50 μm open (or any other pad dimension) with a pitch between 70 μm and 100 μm. Accordingly, embodiments allow for high density I/Os with a small form factor. In an embodiment, the pads 352 may be electrically coupled to dies in the die stacks 320 with wire bonds (not shown). In an embodiment, the pad region 359 may also include SIPD components 353. As noted above, the SIPD components 353 may allow for enhanced testing of the die stacks after the interposer substrate is removed.

Referring now to FIG. 3C, a cross-sectional illustration of the pad region 359 along line C-C′ in FIG. 3B is shown, in accordance with an embodiment. As shown, the thickness of the SIPD components 353 may be less than a thickness of the pads 352. Accordingly, the interposer substrate 360 may first be removed to expose the pads 352 and the SIPD components 353. At this point testing may be implemented to identify functional die modules. After testing, the SIPD components 353 may then be removed with a planarizing or polishing process, leaving behind the pads 353 since the pads 352 are thicker.

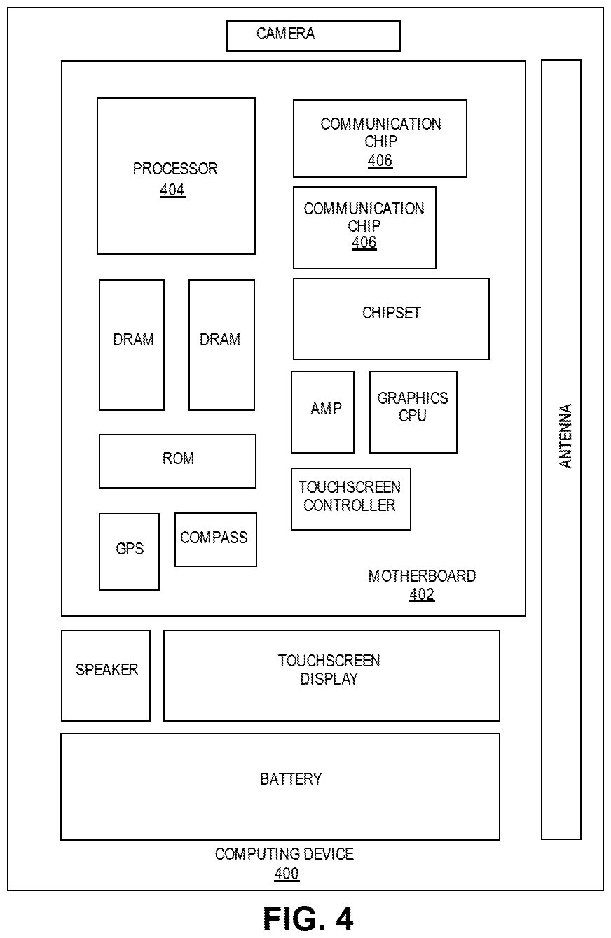

FIG. 4 illustrates a computing device 400 in accordance with one implementation of the invention. The computing device 400 houses a board 402. The board 402 may include a number of components, including but not limited to a processor 404 and at least one communication chip 406. The processor 404 is physically and electrically coupled to the board 402. In some implementations the at least one communication chip 406 is also physically and electrically coupled to the board 402. In further implementations, the communication chip 406 is part of the processor 404.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 406 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processor 404 of the computing device 400 includes an integrated circuit die packaged within the processor 404. In some implementations of the invention, the integrated circuit die of the processor may be packaged in an electronic package with pre-patterned fine-pitch pads, in accordance with embodiments described herein. The term “processor” may refer to any device or portion of a device that processes electronic data from registers and/or memory to transform that electronic data into other electronic data that may be stored in registers and/or memory.

The communication chip 406 also includes an integrated circuit die packaged within the communication chip 406. In accordance with another implementation of the invention, the integrated circuit die of the communication chip may be packaged in an electronic package with pre-patterned fine-pitch pads, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a package substrate; a die stack on the package substrate; a mold layer encapsulating the die stack; and a bond pad having a first surface and a second surface, wherein the die stack is electrically coupled to the first surface of the bond pad with a wire bond, and wherein the second surface of the bond pad is substantially coplanar with a surface of the mold layer.

Example 2: the electronic package of Example 1, further comprising a heat spreader over a surface of the die stack.

Example 3: the electronic package of Example 1 or Example 2, wherein a surface of the heat spreader is substantially coplanar with a surface of the mold layer.

Example 4: the electronic package of Examples 1-3, wherein a thickness of the heat spreader is substantially coplanar with a thickness of the bond pad.

Example 5: the electronic package of Examples 1-4, wherein the heat spreader and the bond pad comprise the same material.

Example 6: the electronic package of Examples 1-5, wherein the die stack is separated from the package substrate by the mold layer.

Example 7: the electronic package of Examples 1-6, further comprising: a wire bond electrically coupling the second surface of the bond pad to the package substrate.

Example 8: the electronic package of Examples 1-7, further comprising: a second die stack positioned above the first die stack.

Example 9: the electronic package of Examples 1-8, wherein the second die stack is encapsulated in a second mold layer.

Example 10: the electronic package of Examples 1-9, further comprising a second bond pad having a first surface and a second surface, wherein the second die stack is electrically coupled to the first surface of the second bond pad with a wire bond, and wherein the second surface of the bond pad is substantially coplanar with a surface of the second mold layer.

Example 11: the electronic package of Examples 1-10, wherein the die stack comprises a plurality of memory dies.

Example 12: the electronic package of Examples 1-11, wherein the die stack comprises four or more memory dies.

Example 13: a die module, comprising: a plurality of dies in a stack; a mold layer encapsulating the plurality of dies; a heat spreader over a surface of one of the plurality of dies, wherein a surface of the heat spreader is substantially coplanar with a first surface of the mold layer; and a bond pad with a first surface and a second surface, wherein a first surface of the bond pad is substantially coplanar with the first surface of the mold layer, and wherein a wire bond electrically couples the second surface of the bond pad to one of the plurality of dies.

Example 14: the die module of Example 13, wherein the plurality of dies are stacked in an offset orientation.

Example 15: the die module of Example 13 or Example 14, wherein the plurality of dies are electrically coupled to each other with one or more wire bonds.

Example 16: the die module of Examples 13-15, wherein a thickness of the bond pad is substantially equal to a thickness of the heat spreader.

Example 17: the die module of Examples 13-16, wherein the bond pad and the heat spreader comprise the same material.

Example 18: the die module of Examples 13-17, wherein the plurality of dies are memory dies.

Example 19: the die module of Examples 13-18, wherein the plurality of dies comprises four or more memory dies.

Example 20: the die module of Examples 13-19, wherein the bond pad is laterally adjacent to the heat spreader.

Example 21: the die module of Examples 13-20, wherein a portion of the mold layer separates a sidewall of the heat spreader from a sidewall of the bond pad.

Example 22: a method of forming a die module, comprising: providing an interposer, wherein the interposer comprises a heat spreader, a bond pad, and an interposer substrate, wherein the heat spreader and the bond pad are positioned over the interposer substrate; attaching a die stack to the heat spreader; wire bonding the die stack to the bond pad; encapsulating the die stack, the heat spreader, and the bond pad with a mold layer; and removing the interposer substrate, wherein removal of the interposer substrate electrically isolates the heat spreader from the bond pad.

Example 23: the method of Example 22, wherein the bond pad is part of a single integrity power delivery (STPD) test module.

Example 24: the method of Example 22 or Example 23, further comprising: dicing the mold layer to separate a plurality of die stacks into individual modules.

Example 25: the method of Examples 22-24, wherein a thickness of the bond pad and a thickness of the heat spreader are substantially equal.

What is claimed is:

1. An electronic package, comprising:
a package substrate;
a die stack on the package substrate;
a mold layer encapsulating the die stack; and
a bond pad having a first surface and a second surface, wherein the die stack is electrically coupled to the first surface of the bond pad with a wire bond, and wherein the second surface of the bond pad is substantially coplanar with a surface of the mold layer.

2. The electronic package of claim 1, further comprising a heat spreader over a surface of the die stack.

3. The electronic package of claim 2, wherein a surface of the heat spreader is substantially coplanar with a surface of the mold layer.

4. The electronic package of claim 2, wherein a thickness of the heat spreader is substantially coplanar with a thickness of the bond pad.

5. The electronic package of claim 2, wherein the heat spreader and the bond pad comprise the same material.

6. The electronic package of claim 1, wherein the die stack is separated from the package substrate by the mold layer.

7. The electronic package of claim 1, further comprising:
a wire bond electrically coupling the second surface of the bond pad to the package substrate.

8. The electronic package of claim 1, further comprising:
a second die stack positioned above the first die stack.

9. The electronic package of claim 8, wherein the second die stack is encapsulated in a second mold layer.

10. The electronic package of claim 9, further comprising a second bond pad having a first surface and a second surface, wherein the second die stack is electrically coupled to the first surface of the second bond pad with a wire bond, and wherein the second surface of the bond pad is substantially coplanar with a surface of the second mold layer.

11. The electronic package of claim 1, wherein the die stack comprises a plurality of memory dies.

12. The electronic package of claim 11, wherein the die stack comprises four or more memory dies.

13. A die module, comprising:
a plurality of dies in a stack;
a mold layer encapsulating the plurality of dies;
a heat spreader over a surface of one of the plurality of dies, wherein a surface of the heat spreader is substantially coplanar with a first surface of the mold layer; and
a bond pad with a first surface and a second surface, wherein a first surface of the bond pad is substantially coplanar with the first surface of the mold layer, and wherein a wire bond electrically couples the second surface of the bond pad to one of the plurality of dies.

14. The die module of claim 13, wherein the plurality of dies are stacked in an offset orientation.

15. The die module of claim 14, wherein the plurality of dies are electrically coupled to each other with one or more wire bonds.

16. The die module of claim 13, wherein a thickness of the bond pad is substantially equal to a thickness of the heat spreader.

17. The die module of claim 13, wherein the bond pad and the heat spreader comprise the same material.

18. The die module of claim 13, wherein the plurality of dies are memory dies.

19. The die module of claim 18, wherein the plurality of dies comprises four or more memory dies.

20. The die module of claim 13, wherein the bond pad is laterally adjacent to the heat spreader.

21. The die module of claim 20, wherein a portion of the mold layer separates a sidewall of the heat spreader from a sidewall of the bond pad.

22. A method of forming a die module, comprising:
providing an interposer, wherein the interposer comprises a heat spreader, a bond pad, and an interposer substrate, wherein the heat spreader and the bond pad are positioned over the interposer substrate;
attaching a die stack to the heat spreader;
wire bonding the die stack to the bond pad;
encapsulating the die stack, the heat spreader, and the bond pad with a mold layer; and
removing the interposer substrate, wherein removal of the interposer substrate electrically isolates the heat spreader from the bond pad.

23. The method of claim 22, wherein the bond pad is part of a single integrity power delivery (STPD) test module.

24. The method of claim 22, further comprising:
dicing the mold layer to separate a plurality of die stacks into individual modules.

25. The method of claim 22, wherein a thickness of the bond pad and a thickness of the heat spreader are substantially equal.
